(19) United States
(12) Patent Application Publication
(10) Pub. No.: US 2026/0333731 A1
(43) Pub. Date: Oct. 22, 2026

(54) SEMICONDUCTOR DEVICE AND METHOD FOR FORMING THE SAME

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Shih-Yen LIN, New Taipei City (TW); Che-Jia CHANG, Taichung City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 19/260,001

(22) Filed: Jul. 3, 2025

Related U.S. Application Data
(60) Provisional application No. 63/791,988, filed on Apr. 21, 2025.

(51) Int. Cl. H10D 30/01; H10D 30/47

(52) U.S. Cl. CPC H10D 30/017; H10D 30/481

(57) ABSTRACT

A method includes forming a gate dielectric layer over a substrate; forming a 2-D material channel layer over the gate dielectric layer; and forming source/drain electrodes over source/drain regions of the 2-D material channel layer, wherein the source/drain electrodes are formed under a temperature lower than a recrystallization temperature of a metal element of the source/drain electrodes.

### PRIORITY CLAIM AND CROSS-REFERENCE

This application claims priority to U.S. Provisional Application Ser. No. 63/791,988, filed Apr. 21, 2025, which are herein incorporated by references in its entirety.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 6B illustrate a semiconductor device in various stages of fabrication in accordance with some embodiments of the present disclosure.

FIG. 7 illustrates a schematic view of a monolayer of an example TMD in accordance with some example embodiments.

FIG. 8 shows experiment results of semiconductor devices in accordance with some example embodiments.

FIG. 9 shows experiment results of semiconductor devices in accordance with some example embodiments.

FIG. 10 shows experiment results of semiconductor devices in accordance with some example embodiments.

FIGS. 11A to 16B illustrate a semiconductor device in various stages of fabrication in accordance with some embodiments of the present disclosure.

FIG. 17 shows experiment results of semiconductor devices in accordance with some example embodiments.

FIG. 18 shows experiment results of semiconductor devices in accordance with some example embodiments.

FIG. 19 shows experiment results of semiconductor devices in accordance with some example embodiments.

FIG. 20 is a cross-sectional view of a semiconductor device in accordance with some example embodiments.

FIG. 21 is a cross-sectional view of a semiconductor device in accordance with some example embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

Two-dimensional (2-D) materials exhibit remarkable optical and electrical properties in a few atomic layer thicknesses, which is advantageous for device applications in the nanometer regime. Consequently, different devices have been demonstrated based on 2-D materials over the past two decades. Graphene, a 2-D material composed of a single layer of carbon atoms arranged in a honeycomb lattice, initiated this exploration. Researchers have been intrigued by its high mobility value observed in one atomic layer thickness. However, the zero bandgap nature of graphene results in low ON/OFF ratios of graphene transistors, posing a challenge to its application in practical logic circuits. As a result, alternative 2-D materials such as transition-metal dichalcogenides (TMDs), black phosphorus, and wide-bandgap hexagonal boron nitride (h-BN) have come into discussion. Unlike graphene, TMDs such as molybdenum disulfide (MoS₂) and tungsten disulfide (WS₂) possess visible bandgaps, leading to transistors with high ON/OFF ratios. Due to its maturity in thin film growth, transistors based on monolayer MoS₂ have become the main stream device in literature. Besides the potential application in electronic devices, monolayer TMDs, being direct bandgap semiconductors, have also found extensive applications in optical devices such as light-emitting devices.

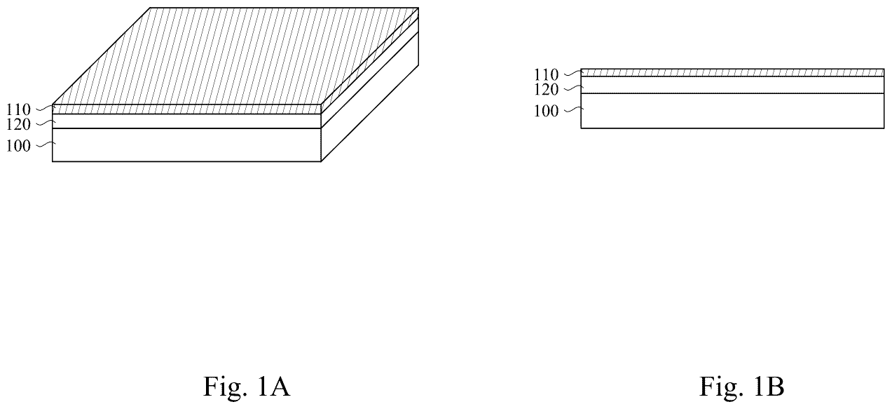

FIGS. 1A to 6B illustrate a semiconductor device in various stages of fabrication in accordance with some embodiments of the present disclosure. In greater details, FIGS. 1B, 2B, 3B, 4B, 5B, and 6B are cross-sectional views along line B-B of top views of FIGS. 1A, 2A, 3A, 4A, 5A, and 6A, respectively.

Reference is made to FIGS. 1A and 1B. Shown there is a substrate 100. In some embodiments, the substrate 100 may be a conductive substrate, such as polysilicon substrate. For example, the substrate 100 may be made of p-doped polysilicon. A dielectric layer 120 is formed over the substrate 100. In some embodiments, the dielectric layer 120 is silicon dioxide (e.g., SiO₂), aluminum oxide (Al₂O₃), hafnium oxide (HfO₂), while in other embodiments the dielectric layer 120 may be a high-k dielectric. In some embodiments, the substrate 100 may serve as a gate electrode of a transistor and the dielectric layer 120 may act a gate dielectric layer of a transistor. Accordingly, the substrate 100 can also be referred to as a gate electrode, and the dielectric layer 120 can also be referred to as a gate dielectric layer. In some embodiments, the dielectric layer 120 and the substrate 100 can be collectively referred to as a gate structure. In some embodiments, the total thickness of the substrate 100 and the dielectric layer 120 is about 300 nm.

A 2-D material channel layer 110 is formed over the dielectric layer 120. As used herein, consistent with the accepted definition within solid state material art, a “2-D material” may refer to a crystalline material consisting of a single layer of atoms. As widely accepted in the art, “2-D material” may also be referred to as a “monolayer” material. In this content, “2-D material” and “monolayer” material are used interchangeably without differentiation in meanings, unless specifically pointed out otherwise. The 2-D material layer may be 2-D materials of suitable thickness. In some embodiments, a 2-D material includes a single layer of atoms in each of its monolayer structure, so the thickness of the 2-D material refers to a number of monolayers of the 2-D material, which can be one monolayer or more than one monolayer. The coupling between two adjacent monolayers of 2-D material includes van der Waals forces, which are weaker than the chemical bonds between/among atoms within the single monolayer. In some embodiments, the 2-D material layer may be a single monolayer structure, or may also be a multi-layer structure, such as about 1 to 10 monolayers. In some embodiments, the 2-D material channel layer 110 has a polycrystalline structure.

In some embodiments, the 2-D material channel layer 110 may be made of transition metal dichalcogenides (TMDs). That is, the 2-D material channel layer 110 may be a metal-containing 2-D material layer. In some embodiment where the 2-D material channel layer 110 includes TMDs monolayer, the TMDs monolayer include molybdenum disulfide (MoS₂), molybdenum diselenide (MoSe₂) molybdenum ditelluride (MoTe₂), tungsten disulfide (WS₂), tungsten diselenide (WSe₂), tungsten ditelluride (WTe₂), or the like.

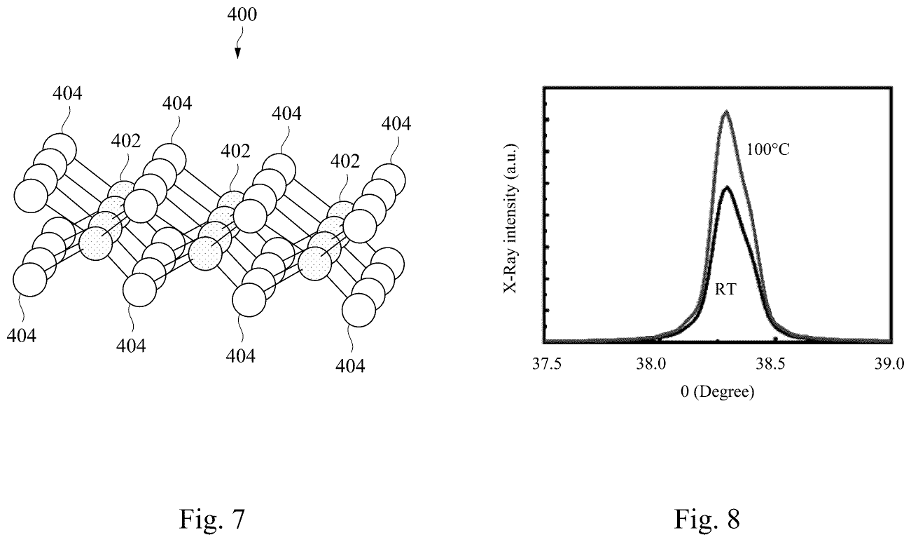

Reference is made to FIG. 7. FIG. 7 illustrates a schematic view of a monolayer 400 of an example TMD in accordance with some example embodiments. In FIG. 7, the one-molecule thick TMD material layer includes transition metal atoms 402 and chalcogen atoms 404. The transition metal atoms 402 may form a layer in a middle region of the one-molecule thick TMD material layer, and the chalcogen atoms 404 may form a first layer over the layer of transition metal atoms 402, and a second layer underlying the layer of transition metal atoms 402. The transition metal atoms 402 may be W atoms or Mo atoms, while the chalcogen atoms 404 may be S atoms, Se atoms, or Te atoms. Throughout the description, the illustrated cross-bonded layers including one layer of transition metal atoms 402 and two layers of chalcogen atoms 404 in combination are referred to as a monolayer 400 of TMD.

Referring back to FIGS. 1A and 1B, the 2-D material channel layer 110 may be made of MoS₂, and the MoS₂ may be formed using the methods described below. Although MoS₂ has exhibited potential applications in optical and electrical devices, most devices may be fabricated with small MoS₂ flakes in micrometer sizes prepared through either mechanical exfoliation or chemical vapor deposition (CVD). These methods are not scalable and would hinder the practical application of MoS₂-based devices. To solve this problem, it has been proposed that wafer-scale MoS₂ films can be obtained through the sulfurization of pre-deposited Mo or MoO₃ thin films. Layer number can be well controlled by using such method. One possible concern on the two-stage growth process of MoS₂ is that a thin Mo/MoO₃ film down to 1.0 nm is usually required to achieve monolayer MoS₂ growth. In this case, the coverage of the Mo/MoO₃ film may not be uniform across the substrate, which may lead to non-uniform or broken MoS₂ film growth after the sulfurization process.

To achieve uniform MoO₃ growth for following sulfurization, an atomic layer deposition technique (ALD) may be adopted for forming the 2-D material channel layer 110 made of MoS₂. Two precursors, molybdenum hexacarbonyl (Mo(Co)₆) and ozone (O₃) are adopted for MoO₃ growth. The carrier gas for the ALD system is nitrogen and the growth temperature is about 180 °C. A deposition cycle for the ALD process involves following steps: (a) a 9-second pulse of Mo(Co)₆, (b) a 3-second purge with nitrogen, (c) a 9-second pulse of O₃, and (d) a 6-second purge with nitrogen. In some embodiments, for a monolayer MoS₂, 6 ALD growth cycles are adopted for MoO₃ growth. After the MoS₃ film is formed, a sulfurization is performed to the MoO₃ film to form the MoS₂ film.

On the other hand, one major advantage of 2-D material is that the thin film can be transferred to different substrates and still maintain their unique electrical and optical characteristics after the film transferring process. Compared with conventional PMMA-assisted film transferring process, the film transferring process by using the PDMS stamping can significantly reduce the PMMA contaminations on 2-D material surface.

In a typical PDMS stamping, a polydimethylsiloxane (PDMS) elastomer stamp is used as a carrier substrate for the material (e.g., the 2-D material channel layer 110 in this case) to be deposited. In some embodiments, the 2-D material channel layer 110 (e.g., MoS₂) is coated on a protruding surface of a PDMS stamp. The 2-D material channel layer 110 is transferred to a substrate (e.g., the dielectric layer 120 in this case), and the PDMS stamp is then peeled off from the 2-D material channel layer 110.

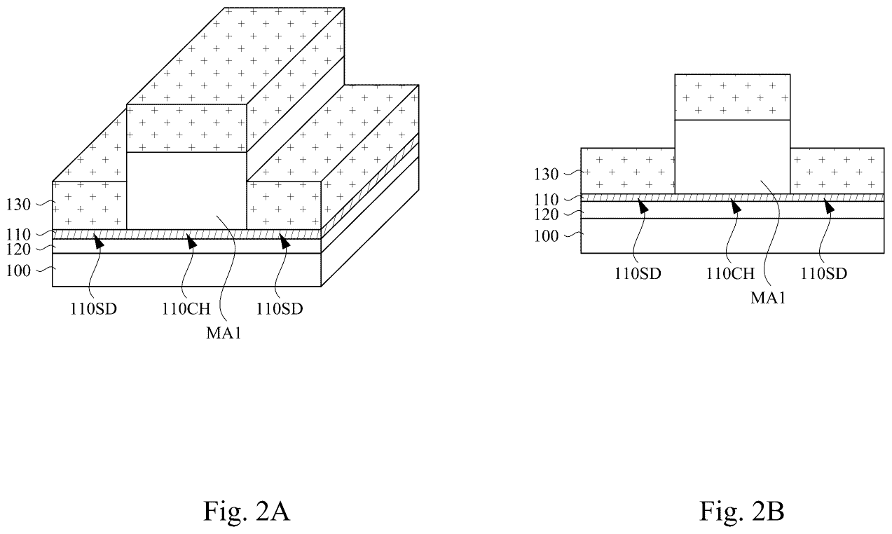

Reference is made to FIGS. 2A and 2B. A patterned mask MA1 is formed over the 2-D material channel layer 110. In greater detail, the patterned mask MA1 may cover channel region 110CH of the 2-D material channel layer 110, and may include openings that expose source/drain regions 110SD of the 2-D material channel layer 110 exposed. In some embodiments, the patterned mask MA1 may be photoresist.

Afterwards, a metal layer 130 is deposited over the substrate 100 and filling the openings of the patterned mask MA1. In greater details, portions of the metal layer 130 is formed in contact with the source/drain regions 110SD of the 2-D material channel layer 110, while other portions of the metal layer 130 is formed on the top surface of the patterned mask MA1.

In some embodiments, the metal layer 130 may include gold (Au), copper (Cu), and platinum (Pt), or other suitable metals. In some embodiments, the metal layer 130 is deposited under a temperature such that the metal layer 130 is formed having a polycrystalline structure. Here, the term “polycrystalline structure” in a metal refers to a material composition characterized by numerous small crystallites or grains having different crystalline structures. Each grain within the structure is a single crystal with its own distinct orientation.

That is, the metal layer 130 is deposited under a temperature less than a recrystallization temperature of the metal element of the metal layer 130, such as about 0.8 to 0.9 times the recrystallization temperature of the metal element of the metal layer 130. In some embodiments, the recrystallization temperature is typically about 0.3 to about 0.4 times the melting point for metal elements. Accordingly, the deposition temperature may be less than 0.3 to 0.4 times the melting point of the metal element of the metal layer 130. In some embodiments, the deposition temperature of the metal layer 130 is about 100 °C to about 200 °C, such temperature can not only results in the metal layer 130 with polycrystalline structure, but can also prevent photoresist (e.g., the patterned mask MA1) from deterioration.

In some embodiments, the recrystallization temperature of gold (Au) is about 200 °C to about 300 °C, and thus the metal layer 130 may be deposited under a temperature less than about 200 °C. In some embodiments, the recrystallization temperature of copper (Cu) is about 200 °C to about 300 °C, and thus the metal layer 130 may be deposited under a temperature less than about 200 °C. In some embodiments, the recrystallization temperature of platinum (Pt) is about 600 °C to about 700 °C, and thus the metal layer 130 may be deposited under a temperature less than about 600 °C.

As shown in FIG. 8, in some embodiments where the metal layer 130 is made of gold (Au), the X-ray diffraction curves of two samples with 100 nm Au deposited on a monolayer MoS₂ surface (e.g., the 2-D material channel layer 110) at room temperature (e.g., 25 °C) and about 100 °C are shown. For both samples, clear Au (111) peaks are observed, which suggests that with the assist of van der Waals epitaxy, a polycrystalline Au film can be observed on the MoS₂ surface. With increasing deposition temperature to 100 °C, minor decrease in the full widths at the half maximum of the Au (111) peak from 0.20 to 0.19 degree is observed, which suggest an enhanced crystallinity of the Au film deposited at 100 °C. The high-resolution transmission electron microscopy image of the sample with 100 nm Au deposited on MoS₂ surface, regular arranged Au atoms are also observed. Although a globally polycrystalline Au film is obtained at the low deposition temperature 100 °C, periodical Au atom alignment along the Au (111) orientation direction can still be observed locally on the MoS₂ surface, which may help to reduce the contact resistance at the Au/MoS₂ interface. In some embodiments, the metal layer 130 may include (111) orientation with a polycrystalline structure.

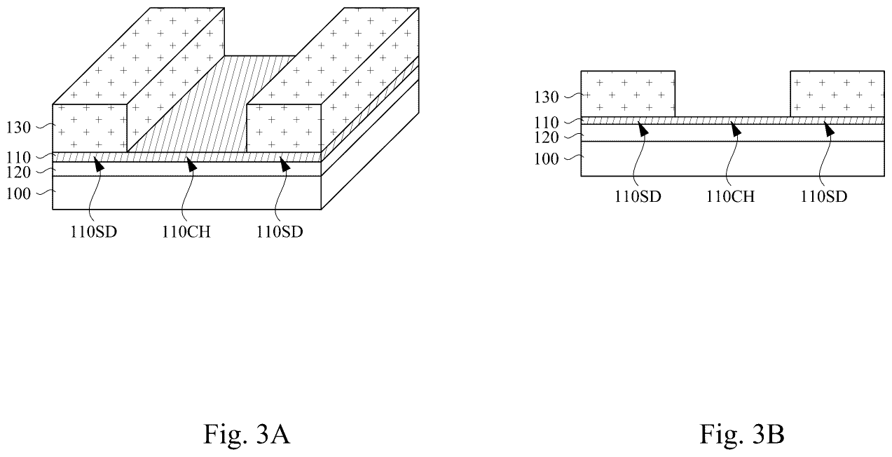

Reference is made to FIGS. 3A and 3B. The patterned mask MA1 is removed, while leaving the portions of the metal layer 130 remaining over the source/drain regions 110SD of the 2-D material channel layer 110. The remaining portions of the metal layer 130 can be referred to as source/drain electrodes 130. On the other hand, portions of the metal layer 130 over the top surface of the patterned mask MA1 will be removed together. In some embodiments, the patterned mask MA1 can be removed using suitable process, such as lift-off process, or other suitable removal process.

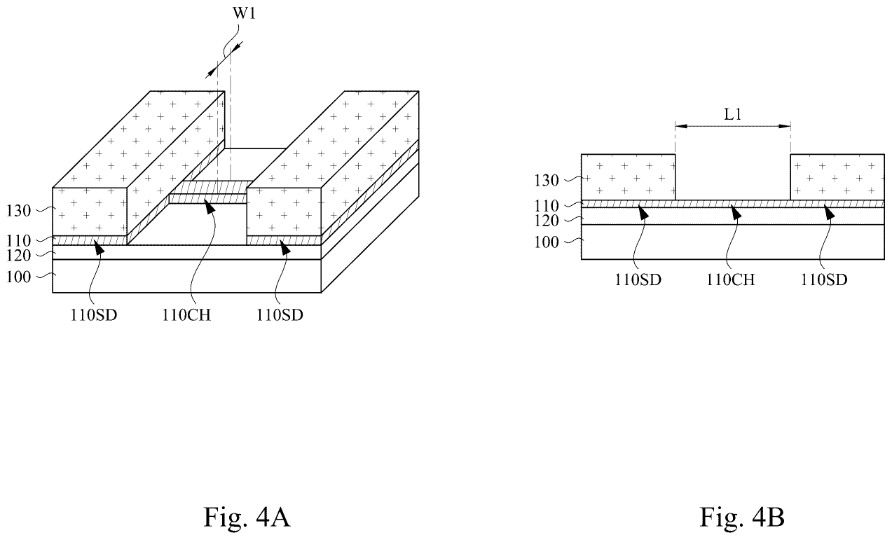

Reference is made to FIGS. 4A and 4B. Portion of the 2-D material channel layer 110 exposed through the source/drain electrodes 130 may be patterned to define the shape of the channel region 110CH of a transistor. For example, the portion of the 2-D material channel layer 110 exposed through the source/drain electrodes 130 is narrowed down along a direction that is substantially perpendicular to a current flow direction. Here, the current flow direction may be the direction from one source/drain electrode 130 to another one source/drain electrode 130. In some embodiments, after the 2-D material channel layer 110 is patterned, portions of the dielectric layer 120 are exposed.

In some embodiments, reactive ion etching (RIE) may be adopted for the channel definition of the transistor after the source/drain electrodes 130 are formed. The channel width W1 and channel length L1 of the channel region 110CH are about 25 μm and 5 μm, respectively.

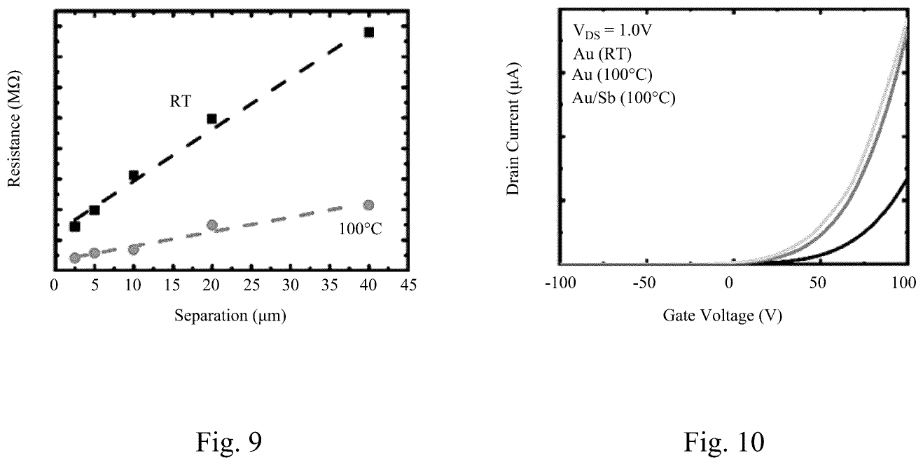

Reference is made to FIG. 9. In some embodiments where the 2-D material channel layer 110 is made of MoS₂ and the source/drain electrodes 130 are made of Au, to investigate the effect of deposition temperatures to the Au electrodes, transfer line model (TLM) simulation is adopted to extract the contact resistance values at the Au/MoS₂ interface. The resistance values of Au electrodes with different deposition temperatures (room temperature and 100 °C) and different separations are shown. Much lower resistance is observed for the sample with 100 °C deposition temperature.

Reference is made to FIG. 10. The transfer curves of devices at V_{DS}=1.0 V with source/drain electrodes 130 made of Au with different deposition temperatures (room temperature and 100 °C) are shown. For comparison, another device with 100 nm Au/50 nm Sb deposited at 100 °C is also fabricated following the same procedure. Although the drain currents of the device with Sb contact electrodes are still slightly higher than the device with Au electrodes deposited at 100 °C, the compatible device performances of the two devices suggest that Au may replace Sb as the contact metals to MoS₂ transistors. Since the work function of Au (5.1 eV) is much higher than Sb (4.16 eV) and Sb may include a single crystalline structure, the results suggest that the crystallinity of the contact electrodes may be a critical issue that influences the contact resistance at the metal/2-D material interface.

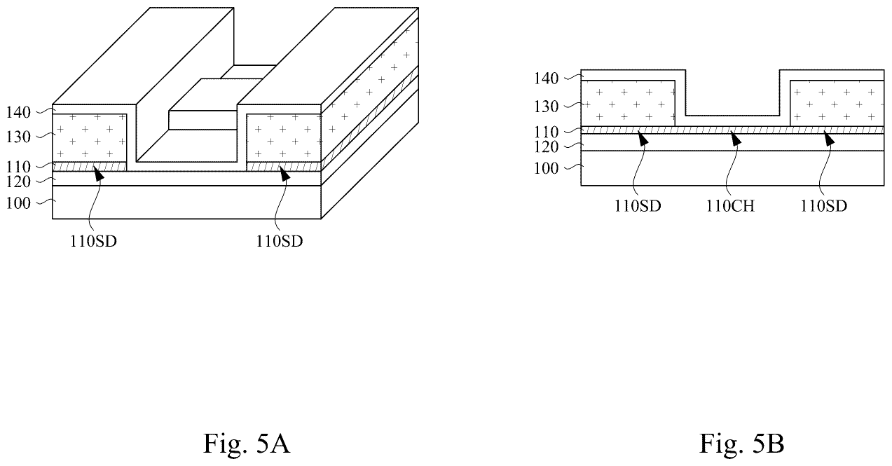

Reference is made to FIGS. 5A and 5B. A passivation layer 140 is formed covering the 2-D material channel layer 110 after the 2-D material channel layer 110 is patterned. As a result, the passivation layer 140 may cover and may be in contact with top surface and sidewalls of the channel region 110CH of the 2-D material channel layer 110. Moreover, the passivation layer 140 may be in contact with the top surface of the dielectric layer 120, and may be in contact with sidewalls and top surface of the source/drain electrodes 130.

The passivation layer 140 may include dielectric material, such as aluminum oxide (Al₂O₃), silicon dioxide (e.g., SiO₂), or other suitable dielectric material. In other embodiments, the passivation layer 140 may include high-k dielectric material, such as hafnium oxide (HfO₂) or zirconium oxide (ZrO₂) In some embodiments, the thickness of the passivation layer 140 is about 30 nm. In some embodiments, the passivation layer 140 may be formed by depositing a 5 nm layer using a physical deposition process (e.g., e-beam evaporation) and followed by a 25 nm layer using a chemical deposition process (e.g., ALD). Because the surface of the 2-D material channel layer 110 lacks dangling bonds to provide nucleation sites for the dielectric materials of the passivation layer 140. If the dielectric material is formed by a chemical deposition, such as ALD process, the precursors may be hard to uniformly distribute over the surface of the 2-D material channel layer 110. However, due to the nature of physical deposition, the vaporized materials or ionized materials may be “dropped over” the surface of the 2-D material channel layer 110, and may include better coverage over the 2-D material channel layer 110 than using a chemical deposition. Accordingly, a thin layer of passivation layer 140 formed by physical deposition may act as a seed layer for the following deposited thick layer of the passivation layer 140, such that the entire passivation layer 140 may have better coverage and uniformity over the 2-D material channel layer 110.

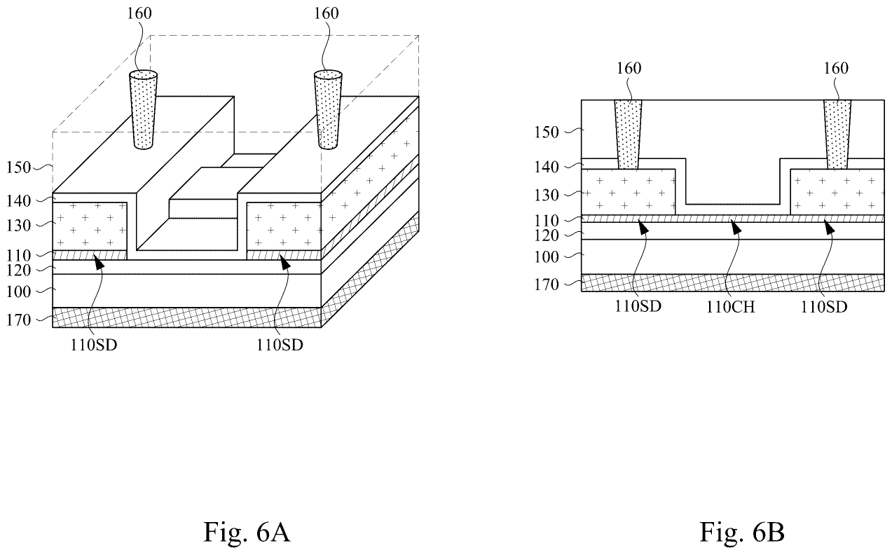

Reference is made to FIGS. 6A and 6B. A dielectric layer 150 is formed over the substrate 100 and over the passivation layer 140. In some embodiments, the dielectric layer 150 may include a dielectric material different from the passivation layer 140. For example, the dielectric layer 150 may be silicon oxide, and the passivation layer 140 may include aluminum oxide. In some embodiments, the dielectric layer 150 is thicker than the passivation layer 140. In some embodiments, at least a portion of the dielectric layer 150 has a bottom surface lower than the top surfaces of the source/drain electrodes 130. In some embodiments, the dielectric constant of the passivation layer 140 may be higher than the dielectric constants of the dielectric layers 120 and 150.

Afterwards, conductive vias 160 are formed extending through the dielectric layer 150 and the passivation layer 140, and in contact with the source/drain electrodes 130, respectively. Then, an electrode layer 170 is formed on the backside of the substrate 100.

In some embodiments, the conductive vias 160 and the electrode layer 170 may include suitable metals, such as copper (Cu) or aluminum (Al). In some embodiments, the deposition temperatures of the conductive vias 160 and the electrode layer 170 may be the same or higher than the deposition temperature of the source/drain electrodes 130. In such embodiments, the crystallinities of the conductive vias 160 and the electrode layer 170 may be higher than the crystallinity of the source/drain electrodes 130. For example, the crystallinity can be measured by X-ray Diffraction (XRD), XRD provides information about the degree of crystallinity, crystal structure, lattice parameters, and preferred orientation (texture). The sharpness and intensity of the diffraction peaks can indicate the level of crystallinity; sharper and more intense peaks typically denote higher crystallinity. In some embodiments, the metal element of the source/drain electrodes 130 may include a lower work function value than the metal elements of the conductive vias 160 and the electrode layer 170, the lower work function value may be beneficial for some N-type channel material, such as MoS₂.

In some embodiments, the deposition temperatures of the conductive vias 160 and the electrode layer 170 may be higher than the recrystallization temperatures of the metal elements of the conductive vias 160 and the electrode layer 170, while lower than the recrystallization temperature of the source/drain electrodes 130. In such embodiments, the conductive vias 160 and the electrode layer 170 may include single crystalline structures, while the source/drain electrodes 130 may include polycrystalline structure.

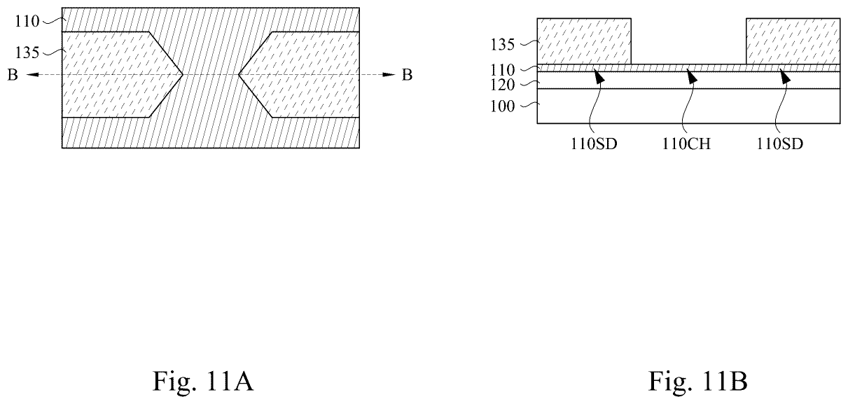

FIGS. 11A to 16B illustrate a semiconductor device in various stages of fabrication in accordance with some embodiments of the present disclosure. In greater details, FIGS. 11B, 12B, 13B, 14B, 15B, and 16B are cross-sectional views along line B-B of FIGS. 11A, 12A, 13A, 14A, 15A, and 16A, respectively. It is noted that some elements of FIGS. 11A to 16B are similar to those described above with respect to FIGS. 1A to 6B, such elements are labeled the same and relevant details will not be repeated for brevity.

Reference is made to FIGS. 11A and 11B. Shown there is a substrate 100. A dielectric layer 120 is formed over the substrate 100. A 2-D material channel layer 110 is formed over the dielectric layer 120. In some embodiments, the substrate 100 may serve as a gate electrode of a transistor and the dielectric layer 120 may act a gate dielectric layer of a transistor. Accordingly, the substrate 100 can also be referred to as a gate electrode, and the dielectric layer 120 can also be referred to as a gate dielectric layer. In some embodiments, the dielectric layer 120 and the substrate 100 can be collectively referred to as a gate structure.

Source/drain pads 135 are formed over the source/drain regions 110SD of the 2-D material channel layer 110. In some embodiments, the source/drain pads 135 may be formed through a similar method as the source/drain electrodes 130 as described above. For example, a patterned mask (not shown) is formed over the 2-D material channel layer 110, and the patterned mask includes openings exposing the source/drain regions 110SD of the 2-D material channel layer 110. A metal layer is deposited over and filling the openings of patterned mask, and then the patterned mask is removed, leaving portions of the metal layer within the openings of patterned mask remaining over the 2-D material channel layer 110 as the source/drain pads 135.

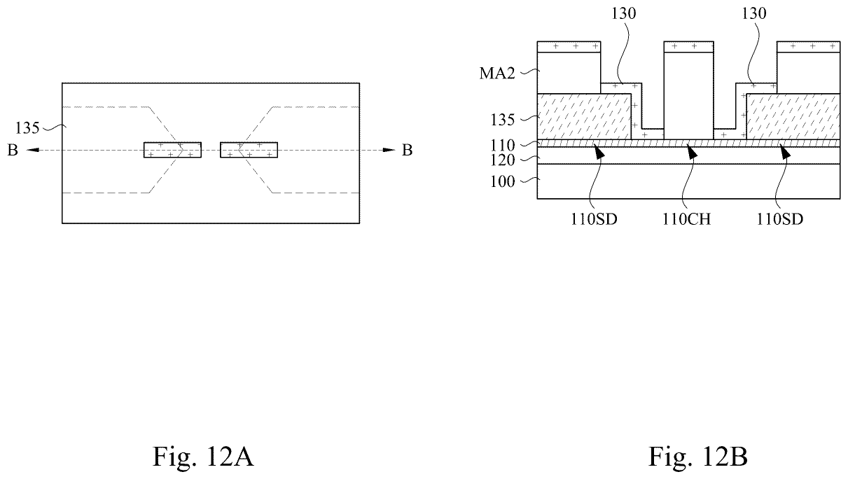

Reference is made to FIGS. 12A and 12B. A patterned mask MA2 is formed over the 2-D material channel layer 110. In greater detail, the patterned mask MA2 may cover channel region 110CH of the 2-D material channel layer 110, and may include openings that expose portions of the source/drain regions 110SD of the 2-D material channel layer 110. In some embodiments, the patterned mask MA2 may be photoresist.

Afterwards, a metal layer 130 is deposited over the substrate 100 and filling the openings of the patterned mask MA2. In greater details, portions of the metal layer 130 is formed in contact with the source/drain regions 110SD of the 2-D material channel layer 110, while other portions of the metal layer 130 is formed on the top surface of the patterned mask MA1.

In some embodiments, the metal layer 130 may include gold (Au), copper (Cu), and platinum (Pt), or other suitable metals. In some embodiments, the metal layer 130 is deposited under a temperature such that the metal layer 130 is formed having a polycrystalline structure. Here, the term “polycrystalline structure” in a metal refers to a material composition characterized by numerous small crystallites or grains. Each grain within the structure is a single crystal with its own distinct orientation.

That is, the metal layer 130 is deposited under a recrystallization temperature of the metal element of the metal layer 130. In some embodiments, the recrystallization temperature is typically 0.3-0.4 times the melting point for pure metal elements. Accordingly, the deposition temperature may be about 0.3-0.4 times the melting point of the metal element of the metal layer 130. In some embodiments, the deposition temperature of the metal layer 130 is about 100 °C to about 200 °C, such temperature can not only results in the metal layer 130 with polycrystalline structure, but can also prevent photoresist (e.g., the patterned mask MA1) from deterioration.

In some embodiments, the recrystallization temperature of gold (Au) is about 200 °C to about 300 °C, and thus the metal layer 130 may be deposited under a temperature less than about 200 °C. In some embodiments, the recrystallization temperature of copper (Cu) is about 200 °C to about 300 °C, and thus the metal layer 130 may be deposited under a temperature less than about 200 °C. In some embodiments, the recrystallization temperature of platinum (Pt) is about 600 °C to about 700 °C, and thus the metal layer 130 may be deposited under a temperature less than about 600 °C

In some embodiments, the source/drain pads 135 may include a same metal as the metal layer 130, and thus the source/drain pads 135 may include a same deposition condition as the metal layer 130, and therefore the same crystalline structure as the metal layer 130.

In other embodiments, the source/drain pads 135 may include a different metal than the metal layer 130. In some embodiments, the source/drain pads 135 may include suitable metals, such as antimony (Sb), copper (Cu), or aluminum (Al). In some embodiments, the deposition temperature of the source/drain pads 135 may be higher than the deposition temperature of the metal layer 130. In such embodiments, the crystallinity of the source/drain pads 135 may be higher than the crystallinity of the metal layer 130. For example, the crystallinity can be measured by X-ray Diffraction (XRD), XRD provides information about the degree of crystallinity, crystal structure, lattice parameters, and preferred orientation (texture). The sharpness and intensity of the diffraction peaks can indicate the level of crystallinity; sharper and more intense peaks typically denote higher crystallinity. In some embodiments, the metal element of the source/drain electrodes 130 may include a lower work function value than the metal element of the source/drain pads 135, the lower work function value may be beneficial for some N-type channel material, such as MoS₂.

In some embodiments, the deposition temperature of the source/drain pads 135 may be higher than the recrystallization temperature of the metal elements of the source/drain pads 135, while lower than the recrystallization temperature of the metal layer 130. In such embodiments, the source/drain pads 135 may include single crystalline structures, while the metal layer 130 may include polycrystalline structure.

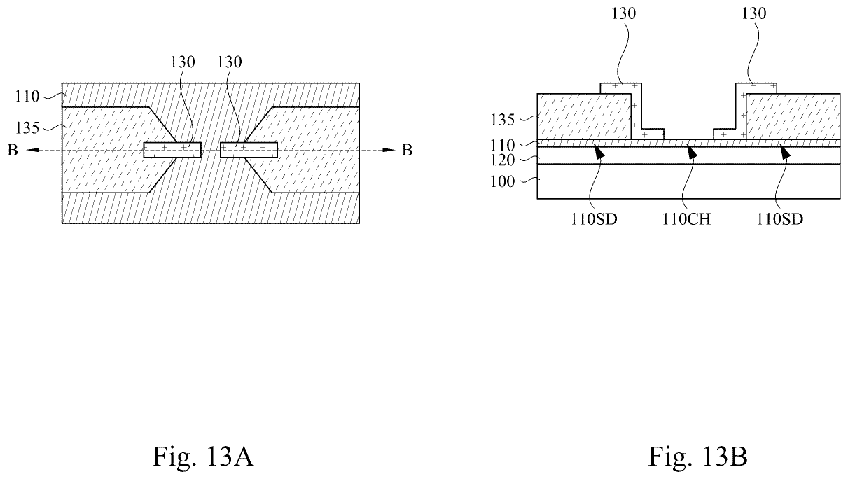

Reference is made to FIGS. 13A and 13B. The patterned mask MA2 is removed, while leaving the portions of the metal layer 130 remaining over the source/drain regions 110SD of the 2-D material channel layer 110. The remaining portions of the metal layer 130 can be referred to as source/drain electrodes 130. On the other hand, portions of the metal layer 130 over the top surface of the patterned mask MA2 will be removed together. In some embodiments, the patterned mask MA2 can be removed using suitable process, such as lift-off process, or other suitable removal process.

In some embodiments, the source/drain electrode 130 extends from top surface of the source/drain pad 135, passing through sidewall of the source/drain pad 135, to top surface of the 2-D material channel layer 110. Such configuration may improve the conductivity between the source/drain electrode 130 and the source/drain pad 135. In some embodiments, the source/drain electrode 130 may be thinner than the source/drain pad 135 along the vertical direction.

Along the current flow direction (e.g., from one source/drain electrode 130 toward another source/drain electrode 130), the shortest distance between the source/drain electrodes 130 is less than the shortest distance between the source/drain pads 135. On the other hand, along the direction perpendicular to the current flow direction, the source/drain electrodes 130 are narrower than the source/drain pads 135. In some embodiments, the source/drain electrodes 130 may be configured to define the actual channel length and channel width of the device.

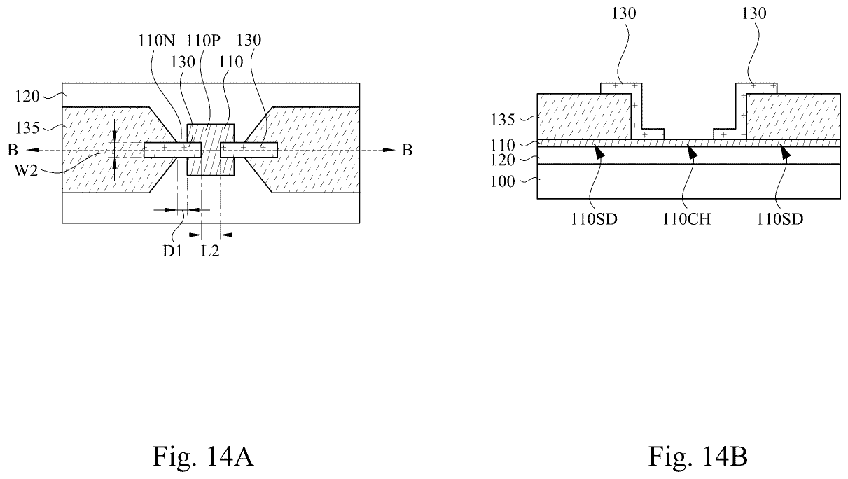

Reference is made to FIGS. 14A and 14B. Portions of the 2-D material channel layer 110 exposed through the source/drain electrodes 130 and the source/drain pads 135 are patterned. In some embodiments, the patterned 2-D material channel layer 110 has a portion 110P between the source/drain electrodes 130 and not covered by the source/drain electrodes 130. In some embodiments, the portion 110P of the 2-D material channel layer 110 is wider than the source/drain electrodes 130 along the direction perpendicular to the current flow direction. In some embodiments, the channel width W2 and channel length L2 the of the 2-D material channel layer 110 are defined by the source/drain electrodes 130, which are about 500 nm and 850 nm, respectively. That is, the 2-D material channel layer 110 may include portions 110N directly below the source/drain electrodes 130, in which the portions 110N are narrower than the portion 110P along the direction perpendicular to the current flow direction. Moreover, the 2-D material channel layer 110 may include portions directly below the source/drain pads 135, and such portions may be wider than the portions 110P and 110N along the direction perpendicular to the current flow direction.

In the top view of FIG. 14A, along the current flow direction, the boundary of the portion 110P and its corresponding source/drain pad 135 has a shortest distance D1 therebetween, in which the distance D1 is a non-zero distance. This can prevent excess current flow from the large electrodes (e.g., the source/drain pads 135) into the channel region 110CH of the 2-D material channel layer 110.

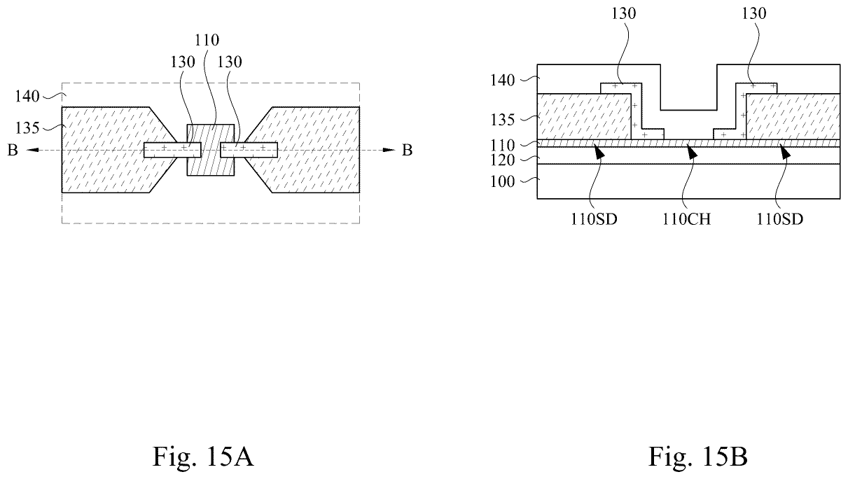

Reference is made to FIGS. 15A and 15B. A passivation layer 140 is formed covering the 2-D material channel layer 110 after the 2-D material channel layer 110 is patterned. As a result, the passivation layer 140 may cover and may be in contact with top surface and sidewalls of the channel region 110CH of the 2-D material channel layer 110. Moreover, the passivation layer 140 may be in contact with the top surface of the dielectric layer 120, and may be in contact with sidewalls and top surface of the source/drain electrodes 130 and the source/drain pads 135.

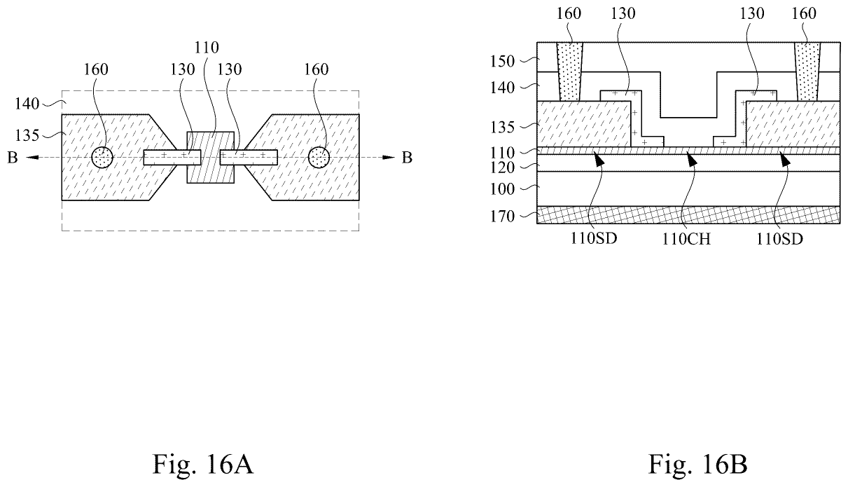

Reference is made to FIGS. 16A and 16B. A dielectric layer 150 is formed over the substrate 100 and over the passivation layer 140. In some embodiments, the dielectric layer 150 may include a dielectric material different from the passivation layer 140. Afterwards, conductive vias 160 are formed extending through the dielectric layer 150 and the passivation layer 140, and in contact with the source/drain electrodes 130, respectively. Then, an electrode layer 170 is formed on the backside of the substrate 100.

It has been demonstrated in previous works that electrons can be stored in MoS₂ layers. The excess electrons stored in the MoS₂ layers may also help to screen the defects in MoS₂ film. With reduced scatterings in the MoS₂ channel, higher field-effect mobility values and drain currents may be observed for multi-layer MoS₂ transistors. For this purpose, sequential transferring up to four times of monolayer MoS₂ films to SiO₂/Si substrate (e.g., the substrate 100 and the dielectric layer 120) is performed. In such embodiments, the 2-D material channel layer 110 includes four monolayers of 2-D material, such as four monolayers of MoS₂ films. In some embodiments, a single monolayer of 2-D material is transferred to the substrate (e.g., on the dielectric layer 120). After the transferring, a high-temperature annealing at about 150 °C under the argon (Ar) environment is performed to smooth out the 2-D material surface. Once the annealing is complete, another monolayer of 2-D material is transferred to the previous monolayer of 2-D material. The transfer-annealing process can be performed several times to obtain desired monolayers of the 2-D material channel layer 110.

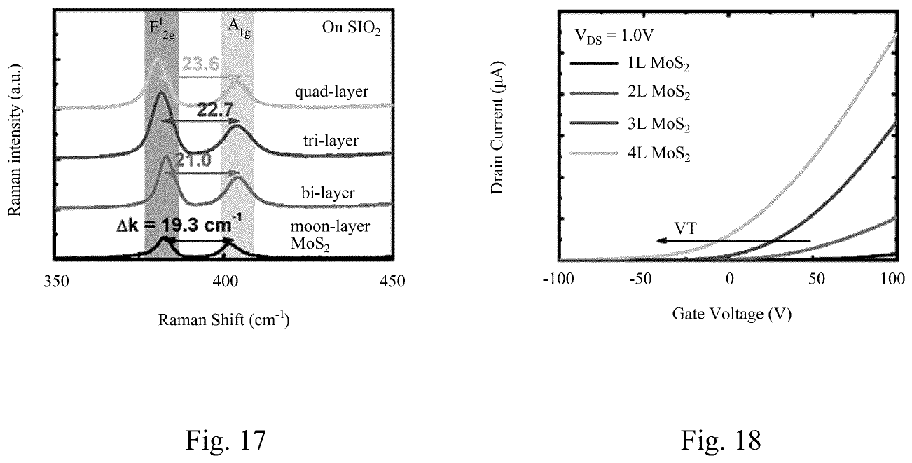

Reference is made to FIG. 17. The Raman spectra of the four samples with 1 to 4 layers of MoS₂ transferring times are shown. TheΔk values of the four samples increase from 19.3, 21.0, 22.7 to 23.6 cm⁻¹ with increasing film transferring times, which indicate that mono-, bi-, tri-and quad-layer MoS₂ are obtained on the substrates. The deposition temperature for the electrodes (e.g., source/drain electrodes 130) is about 100 °C

Reference is made to FIG. 18. The transfer curves of the four devices at V_{DS}=1.0V are shown. Besides the increase in drain currents, the derived field-effect mobility values of the four devices also increase from 4.1, 15.2, 46.5, to 56.4 cm²·V⁻¹·s⁻¹ with increasing MoS₂ monolayers. Also shown in the FIG. 18 is the increasing drain currents at V_{GS}=100.0 V, which is not linearly dependent to the MoS₂ layers. The results suggest that the drain current increase is not solely resulted from the increasing MoS₂ layers.

The other phenomenon observed in FIG. 18 is the gradual threshold voltage V_{T} shift to negate biases with increasing MoS₂ monolayers, which indicates an increasing electron densities are obtained with the stacked MoS₂ monolayers. The results confirm our previous prediction that electron storage will be observed in multi-layer MoS₂. Compared with the large increase in drain currents and field-effect mobility values of bi-and tri-layer MoS₂ transistor, the relatively minor device performance enhancement of the device with quad-layer MoS₂ indicate a saturation in electron storage will be reached with further increase in MoS₂ layers. Three to four monolayers may be sufficient for optimized transistor performances.

The other issue remained to be discussed is the contact resistance at the interface between source/drain electrode and 2-D material channel layer with different MoS₂ monolayers. The derived contact resistance values of four transistors are 1.3×10⁵, 9.7×10³, and 180 Ωum for bi-, tri-and quad-layer transistors, respectively. The results indicate that besides the thicker channel thickness of the quad-layer, the decreasing contact resistance values with increasing monolayer numbers are the other major issue resulting in the enhanced device performances of quad-layer MoS₂ transistor.

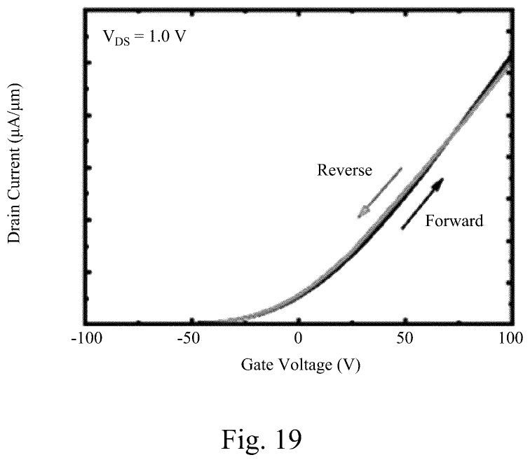

Reference is made to FIG. 19. In some embodiments, the wafer-scale MoS₂ prepared by CVD may include polycrystalline structure, carrier scattering at the grain boundaries may also degrade the device performances. To explore this phenomenon, another device with reduced line widths was fabricated by using the e-beam lithography. The device fabrication procedure is shown in FIGS. 11A to 16B. After quad-layer MoS₂ transferring, 100nm source/drain pads 135 (e.g., Au) are deposited on the MoS₂ surface at 100 °C by using photolithography. Afterward, extended source/drain electrodes 130 (e.g., Au) deposited at 100 °C are fabricated by using the e-beam lithography followed by the metal lift off procedure. To avoid the excess current flow from the large electrodes, the channel definition with reduced line widths is done by using RIE after the extended electrode formation. The channel width and channel length of the device are 500 and 850 nm, respectively. The transfer curves of the device under forward and revise gate biases at V_{DS}=1.0 V are shown in FIG. 19. Compared with the device with larger line widths, even higher field-effect mobility of 105.80 cm²·V⁻¹·s⁻¹ and ON/OFF ratios>10⁵ are observed for the device, which is attributed to the reduced scattering at the grain boundaries with reduced line widths. High drain current density ~130A/m is also observed for the device. The results demonstrate that by stacking polycrystalline monolayer MoS₂ films, compatible performances with the device fabricated on single-crystal MoS₂ can also be obtained. The hysteresis-free transfer curves under forward and reverse gate biases of the device suggest that the passivation layer 140 can effectively prevent the influence from the environment.

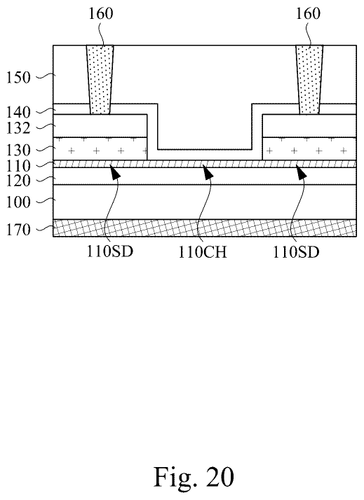

FIG. 20 is a cross-sectional view of a semiconductor device in accordance with some example embodiments. FIG. 20 is similar to FIG. 6B, the difference between FIG. 20 and FIG. 6B is that the device of FIG. 20 further includes source/drain electrodes 132 over the source/drain electrodes 130, respectively. The source/drain electrodes 132 can be formed by, for example, in the process of FIGS. 2A and 2B, sequentially depositing a first metal layer of the source/drain electrodes 130 and a second metal layer of the source/drain electrodes 132 in the opening of the patterned mask MA1, and then removing the patterned mask MA1. In some embodiments, the source/drain electrodes 130 and 132 can be referred to as a first layer and a second layer of a source/drain electrode.

In some embodiments, the source/drain electrodes 132 may include a different metal than the source/drain electrodes 130. In some embodiments, the source/drain electrodes 132 may include suitable metals, such as antimony (Sb), copper (Cu), or aluminum (Al). In some embodiments, the deposition temperature of the source/drain electrodes 132 may be the same or higher than the deposition temperature of the source/drain electrodes 130. In such embodiments, the crystallinity of the source/drain electrodes 132 may be higher than the crystallinity of the source/drain electrodes 130. In some embodiments, the metal element of the source/drain electrodes 130 may include a lower work function value than the metal element of the source/drain electrodes 132, the lower work function value may be beneficial for some N-type channel material, such as MoS₂.

In some embodiments, the deposition temperature of the source/drain electrodes 132 may be higher than the recrystallization temperature of the metal elements of the source/drain electrodes 132, while lower than the recrystallization temperature of the source/drain electrodes 130. In such embodiments, the source/drain electrodes 132 may include single crystalline structure, while the source/drain electrodes 130 may include polycrystalline structure.

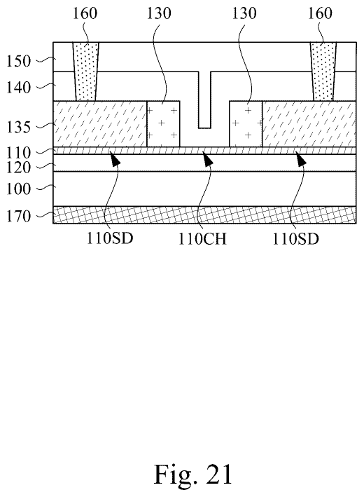

FIG. 21 is a cross-sectional view of a semiconductor device in accordance with some example embodiments. FIG. 21 is similar to FIG. 16B, the difference between FIG. 21 and FIG. 16B is that the device of FIG. 21, the source/drain electrodes 130 may include a same thickness as the source/drain pads 135. That is, top surface of the source/drain electrodes 130 may be substantially level with top surface of the source/drain pads 135.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments provide a method for forming a semiconductor device having 2-D material channel layer. Source/drain electrodes are formed over source/drain regions of the 2-D material channel layer at a temperature lower than the recrystallization temperature of the metal element of the source/drain electrodes, such that the source/drain electrodes may include polycrystalline structure. With such configuration, the device performance may be improved.

In some embodiments of the present disclosure, a method includes forming a gate dielectric layer over a substrate; forming a 2-D material channel layer over the gate dielectric layer; and forming source/drain electrodes over source/drain regions of the 2-D material channel layer, wherein the source/drain electrodes are formed under a temperature lower than a recrystallization temperature of a metal element of the source/drain electrodes.

In some embodiments, the source/drain electrodes have polycrystalline structure.

In some embodiments, the method further includes after forming the source/drain electrodes, patterning a channel region of the 2-D material channel layer between the source/drain regions of the 2-D material channel layer.

In some embodiments, the method further includes after patterning the channel region of the 2-D material channel layer, forming a passivation layer covering a top surface and a sidewall of the channel region of the 2-D material channel layer.

In some embodiments, the passivation layer is made of a high-k dielectric material.

In some embodiments, the method further includes prior to forming the source/drain electrodes, forming source/drain pads over the source/drain regions of the 2-D material channel layer, wherein one of the source/drain electrodes is formed along a top surface and a sidewall of a respective one of the source/drain pads.

In some embodiments, the 2-D material channel layer is made of transition metal dichalcogenide (TMD).

In some embodiments, the 2-D material channel layer has polycrystalline structure.

In some embodiments of the present disclosure, a method includes forming a gate dielectric layer over a gate structure; forming a 2-D material channel layer over the gate dielectric layer, wherein the 2-D material channel layer is made of transition metal dichalcogenide (TMD); and forming source/drain electrodes over source/drain regions of the 2-D material channel layer, wherein the source/drain electrodes have polycrystalline structure.

In some embodiments, the 2-D material channel layer has polycrystalline structure.

In some embodiments, the source/drain electrodes are formed under a temperature that is less than 0.3 to 0.4 times a melting point of a metal element of the source/drain electrodes.

In some embodiments, the method further includes prior to forming the source/drain electrodes, forming source/drain pads over the source/drain regions of the 2-D material channel layer, wherein one of the source/drain electrodes is formed along a sidewall of a respective one of the source/drain pads.

In some embodiments, a crystallinity of the source/drain pads is higher than a crystallinity of the source/drain electrodes.

In some embodiments, the source/drain pads have single crystalline structure.

In some embodiments, the method further includes forming a passivation layer covering a channel region of the 2-D material channel layer, the source/drain pads, and the source/drain electrodes.

In some embodiments of the present disclosure, a semiconductor device includes 2-D material channel layer, wherein the 2-D material channel layer is made of transition metal dichalcogenide (TMD). A gate dielectric layer is over the 2-D material channel layer. A gate electrode is over the gate dielectric layer. Source/drain electrodes are over source/drain regions of the 2-D material channel layer, wherein the source/drain electrodes have polycrystalline structure.

In some embodiments, the semiconductor device further includes source/drain pads over the source/drain regions of the 2-D material channel layer and in contact with the source/drain electrodes, respectively.

In some embodiments, the 2-D material channel layer has a portion between the source/drain electrodes, and wherein along a direction perpendicular to a current flow direction, the portion of the 2-D material channel layer is wider than the source/drain electrodes and is narrower than the source/drain pads.

In some embodiments, in a top view the portion of the 2-D material channel layer has a sidewall facing one of the source/drain pads, and wherein along the current flow direction, the sidewall of the portion of the 2-D material channel layer is spaced apart from the one of the source/drain pads by a non-zero distance.

In some embodiments, n the gate electrode and the source/drain electrodes are disposed on opposite sides of the 2-D material channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a gate dielectric layer over a substrate;
forming a 2-D material channel layer over the gate dielectric layer; and
forming source/drain electrodes over source/drain regions of the 2-D material channel layer, wherein the source/drain electrodes are formed under a temperature lower than a recrystallization temperature of a metal element of the source/drain electrodes.

2. The method of claim 1, wherein the source/drain electrodes have polycrystalline structure.

3. The method of claim 1, further comprising:
after forming the source/drain electrodes, patterning a channel region of the 2-D material channel layer between the source/drain regions of the 2-D material channel layer.

4. The method of claim 3, further comprising:
after patterning the channel region of the 2-D material channel layer, forming a passivation layer covering a top surface and a sidewall of the channel region of the 2-D material channel layer.

5. The method of claim 4, wherein the passivation layer is made of a high-k dielectric material.

6. The method of claim 1, further comprising:
prior to forming the source/drain electrodes, forming source/drain pads over the source/drain regions of the 2-D material channel layer, wherein one of the source/drain electrodes is formed along a top surface and a sidewall of a respective one of the source/drain pads.

7. The method of claim 1, wherein the 2-D material channel layer is made of transition metal dichalcogenide (TMD).

8. The method of claim 7, wherein the 2-D material channel layer has polycrystalline structure.

9. A method, comprising:
forming a gate dielectric layer over a gate structure;
forming a 2-D material channel layer over the gate dielectric layer, wherein the 2-D material channel layer is made of transition metal dichalcogenide (TMD); and
forming source/drain electrodes over source/drain regions of the 2-D material channel layer, wherein the source/drain electrodes have polycrystalline structure.

10. The method of claim 9, wherein the 2-D material channel layer has polycrystalline structure.

11. The method of claim 9, wherein the source/drain electrodes are formed under a temperature that is less than 0.3 to 0.4 times a melting point of a metal element of the source/drain electrodes.

12. The method of claim 9, further comprising:
prior to forming the source/drain electrodes, forming source/drain pads over the source/drain regions of the 2-D material channel layer, wherein one of the source/drain electrodes is formed along a sidewall of a respective one of the source/drain pads.

13. The method of claim 12, wherein a crystallinity of the source/drain pads is higher than a crystallinity of the source/drain electrodes.

14. The method of claim 13, wherein the source/drain pads have single crystalline structure.

15. The method of claim 12, further comprising forming a passivation layer covering a channel region of the 2-D material channel layer, the source/drain pads, and the source/drain electrodes.

16. A semiconductor device, comprising:
a 2-D material channel layer, wherein the 2-D material channel layer is made of transition metal dichalcogenide (TMD);
a gate dielectric layer over the 2-D material channel layer;
a gate electrode over the gate dielectric layer; and
source/drain electrodes over source/drain regions of the 2-D material channel layer, wherein the source/drain electrodes have polycrystalline structure.

17. The semiconductor device of claim 16, further comprising source/drain pads over the source/drain regions of the 2-D material channel layer and in contact with the source/drain electrodes, respectively.

18. The semiconductor device of claim 17, wherein the 2-D material channel layer has a portion between the source/drain electrodes, and wherein along a direction perpendicular to a current flow direction, the portion of the 2-D material channel layer is wider than the source/drain electrodes and is narrower than the source/drain pads.

19. The semiconductor device of claim 18, wherein in a top view the portion of the 2-D material channel layer has a sidewall facing one of the source/drain pads, and wherein along the current flow direction, the sidewall of the portion of the 2-D material channel layer is spaced apart from the one of the source/drain pads by a non-zero distance.

20. The semiconductor device of claim 16, wherein the gate electrode and the source/drain electrodes are disposed on opposite sides of the 2-D material channel layer.
